(19) United States
(12) Patent Application Publication
(10) Pub. No.: US 2013/0160810 A1
(43) Pub. Date: Jun. 27, 2013

(54) PHOTOVOLTAIC DEVICE AND METHOD OF MAKING

(71) Applicants: Bastiaan Arie Korevaar, Schenectady, NY (US); James Neil Johnson, Scotia, NY (US); Oleg Sulima, Ballston Lake, NY (US)

(72) Inventors: Bastiaan Arie Korevaar, Schenectady, NY (US); James Neil Johnson, Scotia, NY (US); Oleg Sulima, Ballston Lake, NY (US)

(73) Assignee: GENERAL ELECTRIC COMPANY, SCHENECTADY, NY (US)

(21) Appl. No.: 13/334,177

(22) Filed: Dec. 22, 2011

(51) Int. Cl. H01L 31/0264; H01L 31/18; H01L 31/0368; H01L 31/075; H01L 31/042

(52) U.S. Cl. 136/244; 136/260; 136/258; 438/87; 257/E31.004

(57) ABSTRACT

A photovoltaic device having n-i-p or p-i-n configuration is presented. The device includes a first semiconductor layer, a second semiconductor layer and an intrinsic layer interposed between the first semiconductor layer and the second semiconductor layer. The intrinsic layer includes cadmium, tellurium and oxygen. Method of making a photovoltaic device is also provided.

### BACKGROUND

The invention generally relates to photovoltaic devices. More particularly, the invention relates to photovoltaic devices that include an “n-i-p” or “p-i-n” configuration.

Thin film solar cells or photovoltaic devices often include a plurality of semiconductor layers disposed on a transparent substrate, wherein one layer serves as a window layer and a second layer serves as an absorber layer. The window layer allows the penetration of solar radiation to the absorber layer, where the optical energy is converted to usable electrical energy. Cadmium telluride/cadmium sulfide (CdTe/CdS) heterojunction-based photovoltaic cells are one such example of thin film solar cells.

Cadmium telluride (CdTe)-based photovoltaic devices typically demonstrate relatively low power conversion efficiencies, which may be attributed to a relatively low open circuit voltage (V_{oc}) in relation to the band gap of the material which is due, in part, to the low effective carrier concentration and a short carrier lifetime in CdTe. Effective carrier concentration of CdTe may be improved by doping with p-type dopants. However, carrier lifetime and carrier concentration are typically coupled in photovoltaic devices, which means that increase in carrier density may lead to a decrease in carrier lifetime. The short carrier lifetime may be attributed to the high defect density that usually occurs when a CdTe thin film is grown.

Further, there is an increased interest in photovoltaic devices with “n-i-p” or “p-i-n” configuration. The devices with n-i-p or p-i-n configuration typically possess high efficiency and high device performance, which may be attributed to wide band gap intrinsic layer.

It would therefore be desirable to provide improved photovoltaic devices having n-i-p or p-i-n configuration.

### BRIEF DESCRIPTION OF THE INVENTION

Various embodiments of the present invention relate to a photovoltaic device having n-i-p or p-i-n configuration.

One embodiment is a photovoltaic device including a first semiconductor layer, a second semiconductor layer and an intrinsic layer interposed between the first semiconductor layer and the second semiconductor layer. The intrinsic layer includes cadmium, tellurium and oxygen.

In one embodiment, a photovoltaic device includes a first semiconductor layer disposed on a first electrically conductive layer disposed on a support. A second semiconductor layer is disposed on the first semiconductor layer, and a second electrically conductive layer is disposed on the second semiconductor layer. The device further includes an intrinsic layer interposed between the first semiconductor layer and the second semiconductor layer. The intrinsic layer includes cadmium, tellurium and oxygen. One embodiment is a photovoltaic module having a plurality of photovoltaic devices as described herein.

One embodiment is a method. The method includes disposing an intrinsic layer on a first semiconductor layer, and disposing a second semiconductor layer on the intrinsic layer, wherein the intrinsic layer includes cadmium, tellurium and oxygen. Disposing the intrinsic layer includes disposing the intrinsic layer in an oxygen-containing environment.

### DRAWINGS

These and other features, aspects, and advantages of the present invention will become better understood when the following detailed description is read with reference to the accompanying drawings in which like characters represent like parts throughout the drawings, wherein:

FIG. 1 is a schematic of a photovoltaic device, according to one embodiment of the invention;

FIG. 2 is a schematic of a photovoltaic device, according to one embodiment of the invention;

FIG. 3 is a schematic of a photovoltaic device, according to one embodiment of the invention;

### DETAILED DESCRIPTION

As discussed in detail below, some of the embodiments of the invention include photovoltaic devices with n-i-p or p-i-n configurations. Further, some of the embodiments of the invention include photovoltaic devices including a first-type semiconductor layer (for example, n-type CdS), a second-type semiconductor layer (for example, p-type CdTe), and an intrinsic layer interposed between the first-type semiconductor layer and the second-type semiconductor layer. The intrinsic layer includes cadmium, tellurium and oxygen. The oxygen concentration in the intrinsic layer (for example, CdTe) passivates various defects in the intrinsic layer, which allows high carrier lifetime. Further, oxygen in the intrinsic CdTe layer provides low carrier density, and thus creates fully depleted CdTe layer within the devices.

Approximating language, as used herein throughout the specification and claims, may be applied to modify any quantitative representation that could permissibly vary without resulting in a change in the basic function to which it is related. Accordingly, a value modified by a term or terms, such as “about”, is not limited to the precise value specified. In some instances, the approximating language may correspond to the precision of an instrument for measuring the value.

In the following specification and the claims, the singular forms “a”, “an” and “the” include plural referents unless the context clearly dictates otherwise.

The terms “first,” “second,” and the like, herein do not denote any order, quantity, or importance, but rather are used to distinguish one element from another.

The terms “transparent region” and “transparent layer” as used herein, refer to a region or a layer that allows an average transmission of at least 80% of incident electromagnetic radiation having a wavelength in a range from about 300 nm to about 850 nm. As used herein, the term “disposed on” refers to layers disposed directly in contact with each other or indirectly by having intervening layers therebetween, unless otherwise specifically indicated.

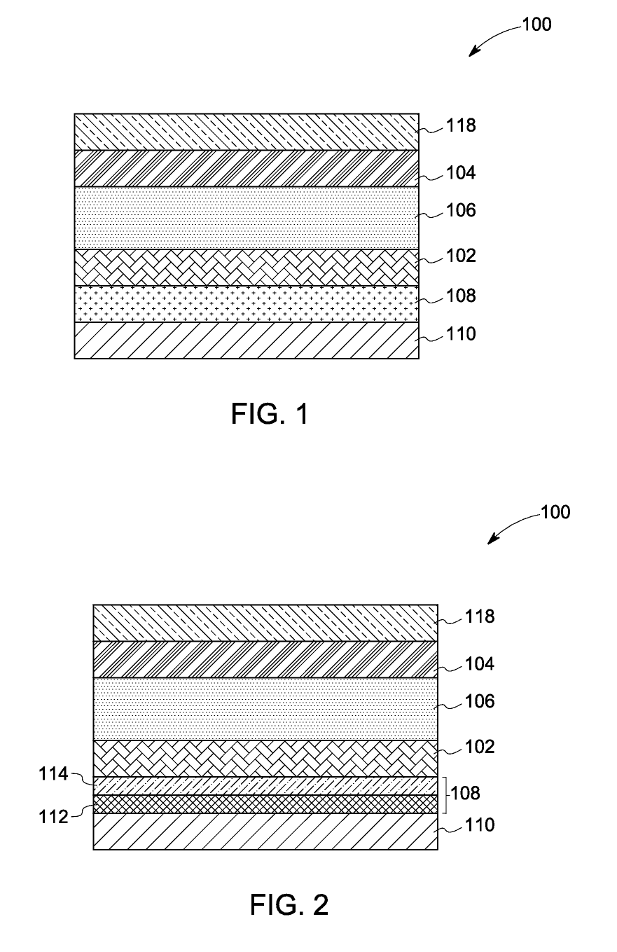

As discussed in detail below, some embodiments of the invention are directed to a photovoltaic device having an “n-i-p” or “p-i-n” configuration or structure. A photovoltaic device 100, according to one embodiment of the invention, is illustrated in FIGS. 1-3. As shown in FIGS. 1-3, the photovoltaic device 100 includes a first semiconductor layer 102, a second semiconductor layer 104, and an intrinsic layer 106 interposed between the first semiconductor layer 102 and the second semiconductor layer 104. The term “interposed” as used herein means that the intrinsic layer is disposed between the first and the second semiconductor layers, either directly adjacent or with one or more intervening intermediate layers.

In some embodiments, the first semiconductor layer and the second semiconductor layer, respectively, include a first-type semiconductor material and a second-type semiconductor material. As used herein, the terms “first-type” and “second-type’ semiconductor material refer to a type of a doped semiconductor material. Those skilled in the art are familiar that a doped semiconductor may be n-type or p-type based on a dopant introduced to the semiconductor. According to most embodiments of the invention, the first semiconductor layer 102 and the second semiconductor layer 104 may be oppositely doped to form a hetero-junction. As used in this context, a hetero-junction is a semiconductor junction that is composed of layers of dissimilar semiconductor materials. These materials usually have non-equal band gaps. As an example, a hetero-junction can be formed by disposing a layer or region of one conductivity type on a layer or region of opposite conductivity, e.g., a “p-n” junction or a “p-i-n” structure.

A three-layer sandwich (n-i-p or p-i-n) structure is usually formed with a middle intrinsic (or i-type) layer between an n-type layer and a p-type layer. This geometry sets up an electric filed between the n-type and p-type layers (or regions) that stretches across the middle intrinsic resistive layer or region.

The first semiconductor layer 102 may be a window layer, according to some embodiments of the invention. The term “window layer” as used herein refers to a substantially transparent layer that forms a hetero-junction with an absorber layer. In some embodiments, the window layer 102 includes an n-type semiconductor material. Non-limiting exemplary materials for the window layer 102 include cadmium sulfide (CdS), indium sulfide (In₂S₃), indium selenide (In₂Se₃), zinc sulfide (ZnS), (ZnTe), zinc selenide (ZnSe), cadmium selenide (CdSe), zinc oxihydrate (Zn(OH)), or combinations thereof. In a particular embodiment, the window layer 102 includes n-type CdS.

Typically, an intrinsic layer is a layer of semiconductor material, used in a photovoltaic device, whose properties are substantially same as those of the undoped material. As used herein, the term “intrinsic layer” refers to a semiconductor layer having an effective carrier density of less than about 10¹⁴ per cubic centimeter (cc). As described previously, the term “effective carrier density” refers to the average concentration of free holes or electrons in a material. As will be recognized by those skilled in the art, carrier concentrations in this range may be achieved for both actively doped material and material formed without the active introduction of dopants. As used in this context, “active dopant” or “actively doped” refers to doping a semiconductor material to be n-type or p-type. In some embodiments, the intrinsic layer includes a semiconductor material that is not doped. In some other embodiments, the semiconductor material may be lightly p-doped, for example less than about 10¹⁴ cm⁻³, and in some instances, less than about 10¹³ cm⁻³.

In one embodiment, the intrinsic layer 106 is an absorber layer. The term “absorber layer”, as used herein, refers to a semiconductor layer wherein the electromagnetic radiation is absorbed and converted to electron-hole pairs. Typically, when solar radiation is incident on the photovoltaic device, electrons in the absorber layer are excited from a lower energy “ground state,” in which they are bound to specific atoms in the solid, to a higher “excited state,” in which they can move through the solid, and generate electron-hole pairs (charge carriers). The electron-hole pairs generated in the intrinsic layer are separated by an internal field generated by the respective doped semiconductor layers, so as to create the photovoltaic current. In this manner, the device 100, when exposed to appropriate illumination, generates a photovoltaic current, which is collected by the electrically conductive layers 108 and 118, which are in electrical communication with appropriate layers of the device.

The intrinsic layer 106 includes cadmium, tellurium and oxygen. In some embodiments, the intrinsic layer 106 includes cadmium telluride. In certain embodiments, the intrinsic layer comprises oxygen-containing cadmium telluride (CdTe) (also referred to as oxygenated cadmium telluride).

Typically, CdTe thin films suffer from high defect density, and as a result a short carrier lifetime (for example, <1 nanoseconds). Inventors of the present invention have observed that incorporation of high content of oxygen in a CdTe layer increases the carrier lifetime. The high carrier lifetime may be attributed to passivation of various defects by oxygen. Additionally, it has also been observed that the high oxygen containing CdTe layer possesses low carrier density. Thus, a CdTe layer with high oxygen content, advantageously, has lower carrier density (such as a carrier density sufficiently low to meet the criterion for “intrinsic” as set forth herein) and increased carrier lifetime as compared to existing CdTe layers, which is required for an intrinsic layer.

In some embodiments, the intrinsic layer 106 may have a concentration of oxygen at least about 1×10¹⁹ cm⁻³. In some embodiments, the concentration of oxygen may range from about 1×10¹⁹ cm⁻³ to about 1×10²¹ cm⁻³ in the intrinsic layer 106. As described above, the high oxygen concentration in the intrinsic layer 106 may increase the carrier lifetime and lower the effective carrier density, and thus create a substantially depleted layer. In some embodiments, the effective carrier density of the intrinsic layer 106 may be lower than the effective carrier density of a CdTe layer without oxygen. In some embodiments, the effective carrier density of the intrinsic layer 106 may range from about 5×10¹² cm⁻³ to about 1×10¹⁴ cm⁻³. In some embodiments, the carrier lifetime in the intrinsic layer 106 is greater than about 2 nanoseconds (ns).

Moreover, CdTe deposition on CdS in the presence of oxygen may be desirable as oxygen at the CdTe/CdS interface may provide improved interface characteristics that may result in higher device efficiencies and enhanced device stability. Without being bound by any theory, it is believed that oxygen at the interface between the window layer 102, and the intrinsic layer 106 (for example, CdS/CdTe) provides improved interface properties (for example, smaller grain sizes, lower pinhole density, or enhanced alloying among layer constituent elements), allowing for high minority carrier lifetimes at the interface in contact with the window layer.

In some embodiments, the oxygen concentration in the intrinsic layer 106 may be uniformly distributed within the layer, such that the concentration of oxygen may be substantially constant across the thickness of the intrinsic layer 106. In some embodiments, the oxygen concentration may be compositionally graded across the thickness of the intrinsic layer 106. The term “substantially constant” as used in this context means that that the variation in the concentration of oxygen in the intrinsic layer 106 is less than about 10 percent across the thickness of the layer 106. The term “compositionally graded” as used in this context means that a concentration of oxygen continuously changes across a thickness of the intrinsic layer 106. In one embodiment, the concentration of the oxygen may decrease from an interface 120 in contact with the first semiconductor layer 102 to another interface 122 in contact with the second semiconductor layer 104.

In some embodiments, the second semiconductor layer 104 includes a p-type semiconductor material. In one embodiment, the second semiconductor layer 104 has an effective carrier density in a range from about 1×10¹⁶ per cubic centimeter to about 1×10²¹ per cubic centimeter. In certain embodiments, the second semiconductor layer includes a heavily doped p-type semiconductor material, and named as “p+-type semiconductor layer.” The term “p+-type semiconductor layer” as used herein refers to a semiconductor layer having an excess mobile p-type carrier or hole density compared to the p-type charge carrier or hole density in a semiconductor layer. In some embodiments, the second semiconductor layer 104 has an effective carrier density in a range greater than about 1×10¹⁸ per cubic centimeter. In particular embodiment, the second semiconductor layer 104 has an effective carrier density in a range from about 1×10¹⁸ per cubic centimeter to about 1×10²¹ per cubic centimeter.

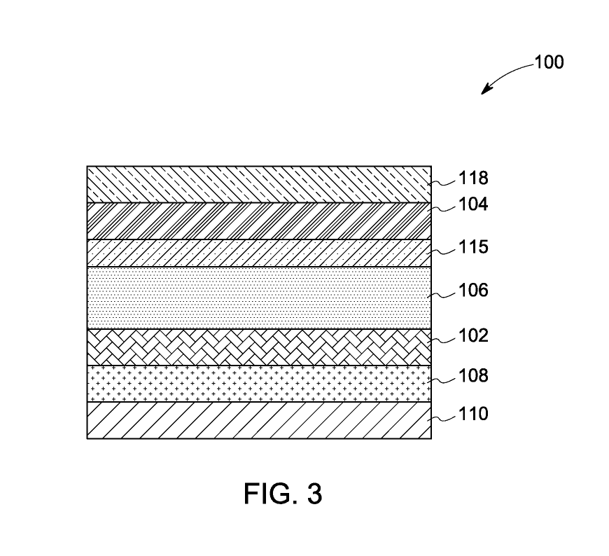

The second semiconductor layer 104 may be a single layer or may have multiple layers. The single layer may include a p-type or p+-type semiconductor material. Multiple layers may have more than one layer, each layer having different material (described below), different type (p-type or p+-type), or different material and type, both. In these instances, multiple layers are arranged according to their increasing effective carrier densities from a layer adjacent to the intrinsic layer towards a top layer adjacent to a back contact layer 118 (referring to FIGS. 3 and 4). It is desirable that the second semiconductor layer 104 has a heavily doped p-type or p+-type surface adjacent to a back contact layer 118. The p+-type surface of the second semiconductor layer 104 may provide a good interface with a back contact layer 118. Higher carrier densities of the p+-type layer may minimize the series resistance of the back contact layer 118, in comparison to other resistances within the device.

Suitable materials for the second semiconductor layer 104 include, but are not limited to, cadmium telluride (CdTe), zinc telluride (ZnTe), magnesium telluride, manganese telluride, beryllium telluride, mercury telluride, arsenic telluride, antimony telluride, copper telluride, cadmium zinc telluride (CdZnTe), copper indium sulphide (CIS), copper indium gallium selenide (CIGS), copper zinc tin sulphide (CZTS), cadmium magnesium telluride (CdMgTe), and cadmium manganese telluride (CdMnTe), or combinations thereof. Some other suitable materials are amorphous Si:H, amorphous SiC:H, crystalline Si, microcrystalline Si:H, microcrystalline SiGe:H, amorphous SiGe:H, amorphous Ge, microcrystalline Ge, GaAs, BaCuSF, BaCuSeF, BaCuTeF, LaCuOS, LaCuOSe, LaCuOTe, LaSrCuOS, LaCuOSe_{0.6}Te_{0.4}, BiCuOSe, BiCaCuOSe, PrCuOSe, NdCuOS, Sr₂Cu₂ZnO₂S₂, Sr₂CuGaO₃S, (Zn,Co,Ni)₃O₄, and combinations thereof.

In some embodiments, the heavily doped p+-type semiconductor layer includes an additional dopant selected from the group consisting of copper, gold, nitrogen, phosphorus, antimony, arsenic, boron, silver, bismuth, sulfur, sodium, and combinations thereof.

The above-mentioned semiconductor materials may be used alone or in combination. Further, these materials may be present in more than one layer, each layer having different type of semiconductor material or having combinations of the materials in separate layers.

In some embodiments, a buffer layer 115 may be disposed between the intrinsic layer 106 and the second semiconductor layer 104, as illustrated in FIG. 4. The second semiconductor layer 104 may be single layer or may have multiple layers, as discussed in the embodiments above. In some instances, the second semiconductor layer 104 is heavily doped p-type layer or a p+-type semiconductor layer (as described previously). The buffer layer 115 provides good interface between the intrinsic layer 106 and the p+-type second semiconductor layer 104. In certain embodiments, suitable materials for the buffer layer 115 may include cadmium magnesium telluride (CdMgTe), and cadmium manganese telluride (CdMnTe). The thickness of the buffer layer 115 may range from about 50 nanometers to about 200 nanometers.

As discussed previously, the first semiconductor layer 102 and the second semiconductor layer 104 are oppositely doped. In some embodiments, the first semiconductor layer 102 may be a p-type layer, and the second semiconductor layer 104 may be an n-type layer to form a “p-i-n” hetero-junction configuration.

In some embodiments, the first semiconductor layer (window layer) 102, the second semiconductor layer 104 or both layers contain oxygen. Without being bound by any theory, it is believed that oxygen introduction to the window layer provides high efficiency and improved device performance. In some embodiments, the amount of oxygen is less than about 25 atomic percent. In some instances, the amount of oxygen is between about 5 atomic percent to about 10 atomic percent. Moreover, the oxygen concentration within the first semiconductor layer, the second semiconductor layer or both layers, may be substantially constant or compositionally graded across the thickness of the respective layer as described above in context of intrinsic layer.

The term “atomic percent” as used herein refers to the atomic concentration or the average number of atoms per unit volume of the oxygen present in a layer. Further, the amount of oxygen as described herein refers to the oxygen concentration in as-deposited layer (for example as deposited window layer 102 or intrinsic layer 106), that is, the concentration prior to any subsequent post-deposition treatment, for example, cadmium chloride treatment. Without being bound by any theory, it is observed that oxygen concentration in as-deposited window layer usually changes during post-deposition processing (for example, CdCl₂ treatment) while the oxygen concentration in as-deposited intrinsic layer remains relatively unchanged by the processing.

The thickness of the window layer is typically desired to be minimized in a photovoltaic device to achieve high efficiency. In some embodiments, the thickness of the window layer i.e. the first semiconductor layer 102 is between about 50 nanometers and about 100 nanometers. In some embodiments, the thickness of the second semiconductor layer 104 ranges from about 50 nanometers to about 200 nanometers. The intrinsic layer 106 is relatively thicker than the first semiconductor layer 102 and the second semiconductor layer 104. Typically, an intrinsic layer is significantly thick to absorb electromagnetic radiation depending on the penetration depth of different wavelengths. In some embodiments, the intrinsic layer 106 has a thickness in the range from about 0.5 micron to about 3.5 microns. In certain embodiments, the thickness of the intrinsic layer 106 ranges from about 1.5 microns to about 3 microns.

In some embodiments, as indicated in FIGS. 1-3, the first semiconductor layer 102 is further disposed on a transparent layer 108 that is disposed on a support 110. In one embodiment, the transparent layer 108 includes an electrically conductive layer (sometimes referred to in the art as a front contact layer) 112 disposed on the support 110, as indicated in FIG. 2. In some embodiments, the first semiconductor layer 102 is disposed directly on the electrically conductive layer 112. In an alternate embodiment, the transparent layer 108 includes an electrically conductive layer 112 disposed on the support 110 and an additional layer 114 interposed between the electrically conductive layer 112 and the window layer 102, as indicated in FIG. 2. In one embodiment, the transparent layer 108 has a thickness in a range from about 100 nanometers to about 600 nanometers.

In one embodiment, the electrically conductive layer 112 includes a transparent conductive oxide (TCO). Non-limiting examples of transparent conductive oxides include cadmium tin oxide (CTO), indium tin oxide (ITO), fluorine-doped tin oxide (SnO:F or FTO), indium-doped cadmium-oxide, cadmium stannate (Cd₂SnO₄ or CTO), doped zinc oxide (ZnO), such as aluminum-doped zinc-oxide (ZnO:Al or AZO), indium-zinc oxide (IZO), and zinc tin oxide (ZnSnOₓ), or combinations thereof. Depending on the specific TCO employed and on its sheet resistance, the thickness of the electrically conductive layer 112 may be in a range of from about 50 nm to about 600 nm, in one embodiment.

The additional layer 114 (optional) is a high resistance transparent (HRT) layer. In one embodiment, the thickness of the HRT layer 114 is in a range from about 50 nm to about 200 nm Non-limiting examples of suitable materials for the HRT layer 114 include tin dioxide (SnO₂), zinc tin oxide (ZTO), zinc-doped tin oxide (SnO₂:Zn), zinc oxide (ZnO), indium oxide (In₂O₃), or combinations thereof.

In one embodiment, the support 110 is transparent over the range of wavelengths for which transmission through the support 110 is desired. In one embodiment, the support 110 may be transparent to visible light having a wavelength in a range from about 400 nm to about 1000 nm. In some embodiments, the support 110 includes a material capable of withstanding heat treatment temperatures greater than about 600° C., such as, for example, silica or borosilicate glass. In some other embodiments, the support 110 includes a material that has a softening temperature lower than 600° C., such as, for example, soda-lime glass or a polyimide. In some embodiments certain other layers may be disposed between the transparent layer 108 and the support 110, such as, for example, an anti-reflective layer, a down converting layer, or a barrier layer (not shown).

As indicated in FIGS. 1-4, in such embodiments, the electromagnetic radiation enters from the support 110, and after passing through the transparent layer 108 and the window layer 102, enters the intrinsic layer 106, where the conversion of electromagnetic energy of incident light (for instance, sunlight) to electron-hole pairs (that is, to free electrical charge) occurs.

In one embodiment, the photovoltaic device 100 further includes a second electrically conductive layer 118, as indicated in FIGS. 3 and 4. The second electrically conductive layer 118 is a metal layer, also called a back contact layer 118. The metal layer 118 is disposed on the second semiconductor layer 104. In some embodiments, the metal layer 118 is disposed on a heavily doped p-type i.e. a p+-type semiconductor layer of the second semiconductor layer 104. The high carrier density at the interface of the second semiconductor layer and the back contact layer 118 may provide improved electrical contact between the metal layer 118 and the second semiconductor layer 104. Accordingly, in some embodiments, any suitable metal having the desired conductivity and reflectivity may be selected as the back contact layer 118. Non-limiting examples of the metal for the metal layer 118 include gold, platinum, molybdenum, tungsten, tantalum, palladium, aluminum, chromium, nickel, or silver. In certain embodiments, another metal layer (not shown), for example, aluminum, may be disposed on the metal layer 118 to provide lateral conduction to the outside circuit.

One embodiment is a photovoltaic module. The photovoltaic module may have an array of a number of the photovoltaic devices (described above) electrically connected in series or in parallel.

In one embodiment, a method of making a photovoltaic device is provided. Referring to FIGS. 1-3, in some embodiments, the method includes disposing a transparent layer 108 including an electrically conductive layer 112 on a support 110 by any suitable technique, such as sputtering, chemical vapor deposition, spin coating, spray coating, or dip coating. Referring to FIG. 2, in some embodiments, an optional HRT layer 114 may be deposited on the electrically conductive layer 112 using sputtering to form the transparent layer 108. A first semiconductor layer or window layer 102 may be then deposited on the transparent layer 108. Non-limiting examples of the deposition methods for the n-type semiconductor layer 102 include one or more of close-space sublimation (CSS), vapor transport method (VTM), chemical bath deposition (CBD), sputtering, and electrochemical deposition (ECD).

The method further includes disposing an intrinsic layer 106 on the first semiconductor layer 102, followed by disposing a second semiconductor layer 104 on the intrinsic layer 106. In some embodiments, the method includes disposing a buffer layer 115 on the intrinsic layer followed by disposing the second semiconductor layer 104. The intrinsic layer 106, the buffer layer 115, the second semiconductor layer 104, or three layers may be deposited by close-space sublimation (CSS), vapor transport method (VTM), ion-assisted physical vapor deposition (IAPVD), radio frequency or pulsed magnetron sputtering (RFS or PMS), plasma enhanced chemical vapor deposition (PECVD), or electrochemical deposition (ECD). In particular embodiments, the intrinsic layer 106, the buffer layer 115, the second semiconductor layer 104, or three layers may be deposited by close-space sublimation (CSS), diffused transport deposition (DTD), or vapor transport deposition (VTD).

In some embodiments, the three layers (the intrinsic layer 106, the buffer layer 115 and the second semiconductor layer 104) may be deposited using the same deposition process. In some embodiments, all three layers are deposited by close-space sublimation (CSS), diffused transport deposition (DTD), or vapor transport deposition (VTD). In particular embodiments, the three layers are deposited by diffused transport deposition.

Incorporation of oxygen in a layer (for example, the intrinsic layer 106) may be employed during deposition of source material (for example, CdTe). In some embodiments, the deposition is carried out in the presence of oxygen as a process gas (that is, in an oxygen-containing environment) throughout the growth process. An alternate method uses a source material containing oxygen to deposit a film or layer, in some other embodiments. Typically, particles or atoms are derived from the source material, and are deposited on a substrate or support to form a film. The source material may include an oxidation product of a semiconductor material, according to some embodiments of the invention.

In some instances, the oxygen-containing environment contains oxygen at a partial pressure. The term “partial pressure” as used herein refers to the pressure that a gas (for example, oxygen) in a mixture of gases would exert if it alone occupied the whole volume occupied by the mixture. In some embodiments, the oxygen-containing environment further includes an inert gas (for example, argon or helium). In embodiments where the oxygen-containing environment solely contains oxygen, the term partial pressure refers to the pressure exerted by oxygen in the environment. In some embodiments, oxygen or a mixture of oxygen and the inert gas, is continuously provided in the environment to maintain the desired pressure in a deposition chamber.

The partial pressure of oxygen in the oxygen-containing environment can be maintained at a determined amount depending on one or more of the concentration of oxygen desired in the layer, or the thickness of the layer. In some embodiments, the partial pressure of oxygen in the oxygen-containing environment is in a range greater than about 0.1 Torr. In some embodiments, the partial pressure of oxygen in the oxygen-containing environment is in a range greater than about 1 Torr. In some embodiments, the partial pressure of oxygen in oxygen-containing environment is in a range from about 0.1 Torr to about 10 Torr. In particular embodiments, the partial pressure of oxygen in oxygen-containing environment is in a range from about 1 Torr to about 5 Torr. As discussed previously, a gradient of oxygen concentration within the layer may be obtained by varying the partial pressure of oxygen in the environment.

The partial pressure of oxygen in the oxygen-containing environment may be controlled such that to achieve desired concentration of oxygen in a layer. In some embodiments, the partial pressure of oxygen is controlled by continuously providing oxygen in the environment so that desired partial pressure is maintained. In particular embodiments, the partial pressure of oxygen in the oxygen-containing environment is substantially constant over the time period for deposition of the layer. The term “substantially constant” as used in this context means that the variation in the partial pressure of oxygen in the oxygen-containing environment is less than about 10 percent over the deposition period for the layer. This is in contrast to deposition process where the layer is deposited in a deposition chamber that includes a static supply of oxygen such that the oxygen content in the deposition chamber is not controlled.

The step of disposing the intrinsic layer 106 on the window layer 102 includes disposing the intrinsic layer in a first oxygen-containing environment. The first oxygen-containing environment is oxygen-rich. In certain instances, the deposition of the intrinsic layer 106 is carried out in 100% oxygen environment to achieve high concentration of oxygen. In some instances, disposing the intrinsic layer 106 includes disposing the layer 106 in presence of a continuous flow of oxygen.

In one embodiment, after the step of disposing the intrinsic layer 106, the step of disposing the buffer layer 115, or the step of disposing the second semiconductor layer 104, cadmium chloride (CdCl₂) treatment is carried out. A solution of CdCl₂ or CdCl₂ vapor may be used for the treatment. The treatment with CdCl₂ is known to increase the carrier lifetime of the absorber layer 106. The treatment with cadmium chloride may be followed by an etching or rinsing step. In one embodiment, etching may be carried out using a suitable acid. In other embodiments, the CdCl₂ may be rinsed off the surface, resulting in a stoichiometric cadmium telluride at the interface, mainly removing the cadmium oxide and CdCl₂ residue from the surface, leaving a cadmium-to-tellurium ratio of about 1 at the surface. The etching works by removing non-stoichiometric material that forms at the surface during processing. Other etching techniques known in the art that may result in a stoichiometric cadmium telluride at the back interface may also be employed.

In some embodiments, a p+-type semiconductor layer or a p+-type surface may be disposed by chemically treating the second semiconductor layer 104 to increase the carrier density on the back-side (side in contact with the metal layer and opposite to the intrinsic layer) of the layer 104. In one embodiment, the photovoltaic device 100 may be completed by depositing a back contact layer, for example, a metal layer 118 on the second semiconductor layer 104.

### EXAMPLES

The examples that follow are merely illustrative, and should not be construed to be any sort of limitation on the scope of the claimed invention.

### Preparation of a Cadmium Telluride Photovoltaic Device:

A cadmium telluride photovoltaic device was prepared by depositing a cadmium telluride (CdTe) layer over a cadmium sulfide (CdS) layer deposited on SnO₂:F (FTO) transparent conductive oxide (TCO) coated substrate. The substrate was 3 millimeters thick soda-lime glass, coated with a FTO transparent conductive layer (450 nm) and a thin high resistance transparent ZnSnOₓ (ZTO) layer (100 nm). Cadmium sulfide (CdS) layer was deposited on the ZTO layer in the presence of oxygen (CdS:O (5% O)) at a thickness of about 80 nm.

The CdTe layer was deposited using a close spaced sublimation process at a substrate temperature of about 550 degrees Celsius and a source temperature of about 625 degrees Celsius. During ramping of the substrate and source temperatures, the substrate temperature ramp rate was greater than the source temperature ramp rate. CdTe deposition began when the substrate temperature reached its set point and the source temperature exceeded the substrate temperature. The deposition was carried out for a period to achieve about 3 microns thickness.

The deposited cadmium telluride layers were further treated with cadmium chloride at a temperature of 400 degrees Celsius for about 20 minutes in air. At the end of the stipulated time, the CdTe layers were treated with a copper solution and subjected to annealing at a temperature of 200 degrees Celsius for duration of 18 minutes. Gold was then deposited on each copper treated layer as the back contact by evaporation process to complete the device fabrication process.

### Example 1

Sample 1 was prepared as described above with the CdTe layer deposited in oxygen environment having 6% oxygen (1 Torr oxygen and 15 Torr helium). Sample 1 was characterized for measuring carrier density in the CdTe layer using CV measurements. It was observed that the carrier density in the CdTe layer was about 5×10¹³ cm⁻³, which is relatively lower than the carrier density of about 1-2×10¹⁴ cm⁻³ usually reported in a CdTe layer.

### Example 2

Sample 2 was prepared similar to the photovoltaic device in sample 1 except the deposition of CdTe was carried out in 100 percent oxygen environment at 4 Ton. This step resulted in the deposition of oxygen-rich CdTe layer.

### Comparative Example

A comparative sample 1 was prepared similar to the photovoltaic device in samples 1 except the CdTe layer was deposited in oxygen environment having 1 Torr oxygen and 15 Torr helium. Sample 2 and comparative sample 1 were characterized for measuring minority carrier lifetime using time-resolved photoluminescence (TRPL) measurements. The minority carriers were excited by using two different lasers generating light at about 630 nm and about 810 nm, for measuring carrier lifetimes at interface and in the layer, respectively. Table 1 shows minority carrier life time for sample 2 compared to comparative sample 1 at interface and in the CdTe layer.

TABLE 1
Minority carrier lifetime measurements

Minority carrier Lifetime (ns)

| Sample | At interface | In the layer |
|---|---|---|
| Sample 1 | 2.6 | 3.6 |
| Comparative Sample 1 | 0.65 | 1.1 |

While only certain features of the invention have been illustrated and described herein, many modifications and changes will occur to those skilled in the art. It is, therefore, to be understood that the appended claims are intended to cover all such modifications and changes as fall within the true spirit of the invention.

1. A photovoltaic device, comprising:
a first semiconductor layer;
a second semiconductor layer; and
an intrinsic layer interposed between the first semiconductor layer and the second semiconductor layer, wherein the intrinsic layer comprises cadmium, tellurium and oxygen.

2. The photovoltaic device of claim 1, wherein the first semiconductor layer or the second semiconductor layer is a p-type semiconductor layer.

3. The photovoltaic device of claim 1, wherein the first semiconductor layer or the second semiconductor layer is an n-type semiconductor layer.

4. The photovoltaic device of claim 1, wherein the first semiconductor layer comprises cadmium sulfide, cadmium selenide, zinc selenide, zinc sulfide, indium selenide, indium sulfide, zinc oxihydrate, or a combination thereof.

5. The photovoltaic device of claim 1, wherein the first semiconductor layer has a thickness in a range from about 50 nanometers to about 100 nanometers.

6. The photovoltaic device of claim 1, wherein the first semiconductor layer has an effective carrier density in a range from about 1×10¹⁴ cm⁻³ to about 1×10²⁰ cm⁻³.

7. The photovoltaic device of claim 1, wherein the second semiconductor layer comprises cadmium telluride, zinc telluride, magnesium telluride, manganese telluride, beryllium telluride, mercury telluride, arsenic telluride, antimony telluride, copper telluride, cadmium zinc telluride, cadmium manganese telluride, cadmium magnesium telluride, copper indium sulphide, copper indium gallium selenide, copper zinc tin sulphide or a combination thereof.

8. The photovoltaic device of claim 1, wherein the second semiconductor layer comprises amorphous Si:H, amorphous SiC:H, crystalline Si, microcrystalline Si:H, microcrystalline SiGe:H, amorphous SiGe:H, amorphous Ge, microcrystalline Ge, GaAs, BaCuSF, BaCuSeF, BaCuTeF, LaCuOS, LaCuOSe, LaCuOTe, LaSrCuOS, LaCuOSe_{0.6}Te_{0.4}, BiCuOSe, BiCaCuOSe, PrCuOSe, NdCuOS, Sr₂Cu₂ZnO₂S₂, Sr₂CuGaO₃S, (Zn,Co,Ni)₃O₄, and combinations thereof.

9. The photovoltaic device of claim 1, wherein the second semiconductor layer has a thickness in a range from about 50 nanometers to about 200 nanometers.

10. The photovoltaic device of claim 1, wherein the second semiconductor layer has an effective carrier density in a range from about 1×10¹⁶ cm⁻³ to about 1×10²¹ cm⁻³.

11. The photovoltaic device of claim 1, wherein the second semiconductor layer has an effective carrier density in a range from about 1×10¹⁸ cm⁻³ to about 1×10²¹ cm⁻³.

12. The photovoltaic device of claim 1, wherein the intrinsic layer comprises cadmium telluride.

13. The photovoltaic device of claim 1, wherein the intrinsic layer comprises a concentration of oxygen at least about 1×10¹⁹ cm⁻³.

14. The photovoltaic device of claim 13, wherein the intrinsic layer comprises a concentration of oxygen ranging from about 1×10¹⁹ cm⁻³ to about 1×10²¹ cm⁻³.

15. The photovoltaic device of claim 1, wherein the intrinsic layer has a thickness in a range from about 0.5 micron to about 3 microns.

16. The photovoltaic device of claim 1, wherein the intrinsic layer has an effective carrier density in a range from about 5×10¹² cm⁻³ to about 1×10¹⁴ cm⁻³.

17. The photovoltaic device of claim 1, further comprising a buffer layer interposed between the intrinsic layer and the second semiconductor layer.

18. The photovoltaic device of claim 1, wherein the buffer layer comprises cadmium mangnesium telluride (CdMgTe), cadmium manganese telluride (CdMnTe) or a combination thereof.

19. The photovoltaic device of claim 1, wherein the first semiconductor layer, the second semiconductor layer, or both layers further comprise oxygen.

20. The photovoltaic device of claim 19, wherein the amount of oxygen is less than about 25 atomic percent.

21. The photovoltaic device of claim 1, wherein the first semiconductor layer is disposed on a first electrically conductive layer.

22. The photovoltaic device of claim 1, wherein a second electrically conductive layer is disposed on the second semiconductor layer.

23. A photovoltaic device, comprising:
a support;
a first electrically conductive layer disposed on the support;
a first semiconductor layer disposed on the first electrically conductive layer;
a second semiconductor layer disposed on the first semiconductor layer;
a second electrically conductive layer disposed on the second semiconductor layer; and
an intrinsic layer interposed between the first type semiconductor layer and the second type semiconductor layer, wherein the intrinsic layer comprises cadmium, tellurium and oxygen.

24. A photovoltaic module comprising a plurality of photovoltaic devices as defined in claim 23.

25. A method, comprising:
disposing an intrinsic layer on a first semiconductor layer, wherein the intrinsic layer comprises cadmium, tellurium, and oxygen;
wherein disposing the intrinsic layer comprises:
disposing the intrinsic layer on the first semiconductor layer in an oxygen-containing environment, and
disposing a second semiconductor layer on the intrinsic layer.

26. The method of claim 25, wherein the oxygen-containing environment comprises 100 percent oxygen.
